(19) United States
(12) Patent Application Publication
(10) Pub. No.: US 2021/0408143 A1
(43) Pub. Date: Dec. 30, 2021

(54) ARRAY SUBSTRATE AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Sisi ZHOU, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/630,442

(22) PCT Filed: Sep. 20, 2019
(86) PCT No.: PCT/CN2019/106831

§ 371 Date: Jan. 12, 2020

(30) Foreign Application Priority Data
Aug. 14, 2019 (CN) 201910747876.5

(51) Int. Cl. H01L 27/32; H01L 51/52

(52) U.S. Cl. CPC H01L 27/326; H01L 51/5253; H01L 27/3258; H01L 27/3246

(57) ABSTRACT

The present invention provides an array substrate and a display device. The array substrate includes an underlay, a thin film transistor (TFT) structure layer, and a light-emitting layer. The TFT structure layer is placed on the underlay. The TFT structure layer has multiple leads. The light-emitting layer is arranged on the TFT structure layer. The light-emitting layer includes multiple light-emitting units. A projection of the leads projected on the underlay has no overlapping with a projection of the light-emitting regions projected on the underlay.

### 1. FIELD OF DISCLOSURE

The present relates to a field of display devices and in particular, to an array substrate and a display device.

### 2. DESCRIPTION OF RELATED ART

In the field of display devices, flat-panel displays such as liquid crystal displays (LCDs) and organic light-emitting diode (OLED) displays have gradually replaced cathode-ray tube display. Among the flat-panel displays, OLED display panels have gradually obtained popularity with their unique advantages such as low power consumption, high color saturation, fast response time, and wide viewing angle. In the future, there will be a wide application of OLED display panels in vehicles, mobile phones, tablet computers, computers, and televisions.

Most of the OLED display panels are driven by currents. A working current is transmitted by a source/drain (SD) electrode from a lower bezel of the display panel. Since the source/drain electrode itself has a certain resistance, there is a voltage drop (IR drop) in signal transmission. In other words, a voltage gradually decreases along a direction away from the lower bezel, and an input current decreases correspondingly, which eventually causes uneven brightness of the display panel and affects product performance.

At present, a double-layer SD structure is used to solve the problem of uneven brightness in the OLED display panels, thereby reducing the resistance of the source/drain electrodes and improving the IR-drop problem. However, in the double-layer SD structure, a thickness of a second SD layer is as thick as 700 nm or more, so an organic planarization layer thereon cannot be completely planarized. As a result, a level difference is formed under a light-emitting layer to cause a surface of the light-emitting layer to be not flat, which affects display quality.

### SUMMARY

It is an objective of the present invention to provide an array substrate and a display device to solve a problem that a surface of a light-emitting layer is not flat due to the inability to planarize a double-layer SD structure in the prior art. The problem affects display quality of a conventional display device.

Accordingly, the present invention provides an array substrate. The array substrate comprises an underlay, a thin film transistor (TFT) structure layer, and a light-emitting layer. The TFT structure layer is disposed on the underlay, and the TFT structure layer comprises a plurality of leads. The light-emitting layer is disposed on the TFT structure layer, wherein the light-emitting layer comprises a plurality of light-emitting units, each of the light-emitting units includes a light-emitting region, and a projection of the leads projected on the underlay has no overlapping with a projection of the light-emitting regions projected on the underlay.

The light-emitting units are arranged in an array, and a gap is provided between the light-emitting regions of each two adjacent light-emitting units, and the projection of the leads projected on the underlay falls within a projection of the gaps projected on the underlay.

The light-emitting units comprise at least one of red light-emitting units, green light-emitting units, and blue light-emitting units.

The TFT structure layer comprises a first planarization layer and a second planarization layer. The leads are disposed on the first planarization layer. The second planarization layer is disposed on the first planarization layer and covering the leads.

The light-emitting layer comprises a first electrode disposed on the second planarization layer, two ends of the first electrode are extended out of the light-emitting region, and one end of the first electrode is connected to the lead through the second planarization layer.

The array substrate further comprises a pixel defining layer disposed on the second planarization layer, wherein the pixel defining layer is provided with an opening arranged corresponding to the light-emitting region, and the first electrode in the light-emitting region is exposed from the opening.

The TFT structure layer comprises a source electrode and a drain electrode, and the lead is connected to the drain electrode.

The TFT structure layer comprises:

an active layer disposed on the underlay;

a first gate insulating layer disposed on the active layer;

a first gate electrode layer disposed on the first gate insulating layer;

a second gate insulating layer disposed on the first gate insulating layer and covering the first gate electrode layer;

a second gate electrode layer disposed on the second gate insulating layer; and

an interlayer dielectric layer disposed on the second gate insulating layer and covering the second gate electrode layer;

wherein the source electrode and the drain electrode are disposed on the interlayer dielectric layer and connected to the active layer through the interlayer dielectric layer, the second gate insulating layer, and the first gate insulating layer.

The array substrate further comprises an encapsulation layer and a buffer layer. The encapsulation layer covers the light-emitting layer and the TFT structure layer. The buffer layer is disposed on the underlay, wherein the active layer is disposed on the buffer layer.

The present invention provides a display device. The display device comprises the array substrate mentioned above.

### Advantages of the Present Invention

The present invention provides the array substrate. The leads in the TFT structure layer has no overlapping with the light-emitting units of the light-emitting layer, and therefore a level difference is prevented from being formed under the light-emitting layer, and a surface of each light-emitting unit is flat and even, so that luminous efficiency of each light-emitting unit is improved, display quality of the display device is enhanced, and user experience is improved.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work or paying the premise.

FIG. 1 is a top schematic view illustrating an array substrate according to one embodiment of the present invention; and

FIG. 2 is a schematic view illustrating a layered structure of the array substrate according to one embodiment of the present invention.

### DETAILED DESCRIPTION OF EMBODIMENTS

Preferable embodiments of the present invention will be described with reference to the accompanying drawings. The embodiments enable those skilled in the art to fully understand the present invention, and can ease understanding of the technical content of the present invention. The present invention can be embodied in many different forms, and the protection scope of the invention is not limited to the embodiments described herein.

In the drawings, structurally identical components are denoted by the same reference numerals, and structural or functionally similar components are denoted by like reference numerals. The dimensions and thickness of each component shown in the drawings are for illustrative purposes only, and the invention does not limit the size and thickness of each component. For clarity of illustration, the drawings may exaggerate the thicknesses of some parts.

In addition, the following description of the embodiments of the present invention is intended to be illustrative of the specific embodiments of the present invention. Directional terms mentioned in the present invention, such as “upper”, “lower”, “front”, “rear”, “left”, “right”, “inside”, “outside”, and “lateral”, are only used to ease understanding and describe the present invention in a better and clearer manner, do not indicate or imply that the device or component referred to must have a particular orientation or be used in a particular orientation, and are therefore not to be construed as limiting the invention. Moreover, the terms “first”, “second”, “third”, and the like are used for illustrative purposes only and do not indicate or imply relative importance.

When a component is described as being “on” another component, the component can be placed directly on the another component, but an intermediate component can also be provided between them. In other words, the component is placed on the intermediate component, and the intermediate component is placed on the another component. When a component is described as “mounted to” or “connected to” another component, it is “directly mounted to” or “directly connected to”, or alternatively, the component is “mounted to” or “connected to” the another component through an intermediate component.

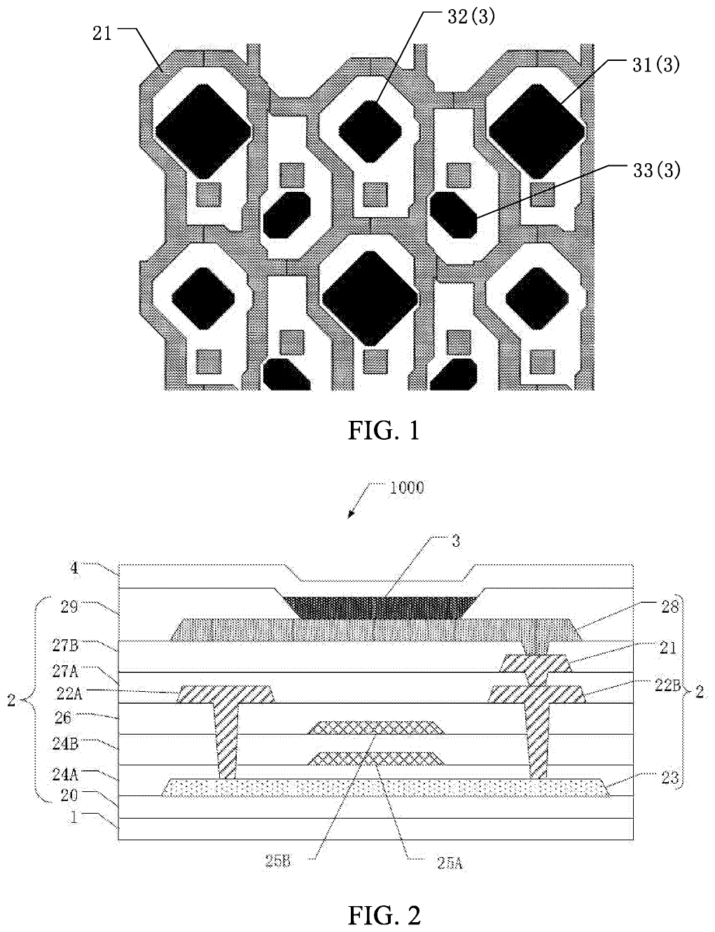

The present invention provides an array substrate 1000. Referring to FIG. 1, the array substrate 1000 comprises an underlay 1, a thin film transistor (TFT) structure layer 2, and a light-emitting layer 3. The thin film transistor (TFT) structure layer 2 is disposed on the underlay 1. The light-emitting layer 3 is disposed on the TFT structure layer 2. The TFT structure layer 2 comprises a plurality of leads 21. The underlay 1 may be an inorganic substrate such as a glass substrate or a quartz substrate, which has water/oxygen barrier properties.

The light-emitting layer 3 comprises a plurality of light-emitting units. The light-emitting units are arranged in an array in the array substrate 1000. The light-emitting units comprise red light-emitting units 32, green light-emitting units 33, and blue light-emitting units 31. The green light-emitting units 33 are arranged corresponding to each other in a plurality of columns. The red light-emitting units 32 and the blue light-emitting units 31 are arranged spaced apart from each other in a plurality of columns. A center of each green light-emitting unit is disposed on a vertical bisector of a virtual line connected between one of the red light-emitting units 32 and one of the blue light-emitting units 31 adjacent thereto. The red light-emitting units 32, the green light-emitting units 33, and the blue light-emitting units 31 together constitute a display screen, thus enabling the display device to realize a color display operation. Moreover, the light-emitting units which are uniformly distributed enable the display device to display a uniform color screen.

The organic light-emitting diode display device has self-luminous properties. Luminous efficiency of the blue light-emitting unit 31 and luminous efficiency of the red light-emitting unit 32 are much lower than that of the green light-emitting unit 33. As a result, if the blue light-emitting unit 31 and the red light-emitting unit 32 have the same pixel size as the green light-emitting unit 33, the blue light-emitting unit 31 and the red light-emitting unit 32 need to increase their current in order to achieve the same brightness as the green light-emitting unit 33, which reduces lifetimes of light-emitting particles in the blue light-emitting unit 31 and the red light-emitting unit 32, thereby reducing a product lifetime of the display device. Therefore, in the present invention, an area of the green light-emitting unit 33 is smaller than an area of the red light-emitting unit 32, and the area of the red light-emitting unit 32 is smaller than an area of each of the blue light-emitting units 31. Furthermore, each green light-emitting unit 33 is shared between two blue light-emitting units 31 and two red light-emitting units 32. With the same display quality, such a design makes the blue light-emitting unit 31 and the red light-emitting unit 32 have a larger area, and at the same time causes the display device to a higher aperture ratio, so that the desired light-emitting intensity can be achieved with a reduced current, thereby prolonging a product lifetime and increasing brightness of the display device.

In the array substrate 1000, each light-emitting unit has a light-emitting region. A projection of the leads projected on the underlay 1 has no overlapping with a projection of the light-emitting regions projected on the underlay 1. In addition, there is a gap between two adjacent light-emitting regions, and the projection of the leads 21 projected on the underlay 1 falls within a projection of the gaps projected on the underlay 1. A distance from an edge of each lead 21 to an edge of the light-emitting region adjacent thereto is less than um. The leads 21 do not overlap each light-emitting region, so that a surface of each light-emitting region of the light-emitting layer 3 is flat, thereby improving the luminous efficiency of each light-emitting unit, enhancing the display performance of the display device, and improving user experience.

Referring to FIG. 2, the TFT structure layer 2 comprises a first planarization layer 27A, a second planarization layer 27B, a first electrode, a pixel defining layer 29, a source electrode 22A, and a drain electrode 22B.

The first planarization layer 27A is disposed between the drain electrode 22B, the source electrode 22A, and the lead 21. The lead 21 is connected to the drain electrode 22B through the first planarization layer 27A. The first planarization layer 27A is used to planarize the source electrode 22A and the drain electrode 22B, protect the source electrode 22A and the drain electrode 22B from water and oxygen, prolong a product lifetime of the display device, and prevent a short circuit. The second planarization layer 27B is disposed on the first planarization layer 27A and covers the leads 21 for planarizing the leads 21, protecting the leads 21 from water and oxygen, prolonging a product lifetime of the display device, and preventing short circuits. The first planarization layer 27A and the second planarization layer 27B are made of an organic insulator.

The first electrode is disposed on a surface of the second planarization layer 27B away from the leads 21. One end of the first electrode is connected to the lead 21 through the second planarization layer 27B. Two ends of the first electrode are extended out of the light-emitting region. The light-emitting layer 3 is disposed on and connected to the first electrode, and the first electrode provides electrical energy to the light-emitting layer 3, so that the light-emitting layer 3 can emit light.

The pixel defining layer 29 is disposed on surfaces of the first electrode and the second planarization layer 27B, wherein the pixel defining layer 29 is provided with an opening arranged corresponding to the first electrode, and each opening is arranged in one of the light-emitting regions. The first electrode in the light-emitting region is exposed from the opening. The light-emitting layer 3 is disposed in the opening. The pixel defining layer 29 is used to define sizes and positions of the light-emitting units of the light-emitting layer 3.

The TFT structure layer comprises an active layer 23, a first gate insulating layer 24A, a second gate insulating layer 24B, a first gate electrode layer 25A, a second gate electrode layer 25B, and an interlayer dielectric layer 26.

The active layer 23 is disposed on the underlay 1 and may be made of one of semiconductor materials such as low temperature polysilicon, amorphous silicon, and oxide semiconductor. The first gate insulating layer 24A is disposed on the active layer 23 and covers the same for electrically insulating the active layer 23 from a gate structure layer, thereby preventing short circuits and protecting the active layer 23.

The gate structure layer is disposed on a surface of the first gate insulating layer 24A away from the active layer 23. The gate structure layer comprises the first gate electrode layer 25A, the second gate electrode layer 25B, the second gate insulating layer 24B, and the interlayer dielectric layer 26. The first gate electrode layer 25A is disposed on the first gate insulating layer 24A and arranged corresponding to the active layer 23. The second gate insulating layer 24B covers the first gate electrode layer 25A and the first gate insulating layer 24A. The second gate insulating layer 24B is used to electrically insulate the first gate electrode layer 25A from the second gate electrode layer 25B to prevent short circuits and protect the first gate electrode layer 25A. The second gate electrode layer 25B is disposed on a surface of the second gate insulating layer 24B away from the first gate electrode layer 25A and arranged corresponding to the active layer 23. The interlayer dielectric layer 26 covers surfaces of the second gate electrode layer 25B and the second gate insulating layer 24B. The source electrode 22A and the drain electrode 22B are disposed on a surface of the interlayer dielectric layer 26 away from the second gate electrode layer 25B. The interlayer dielectric layer 26 is used to electrically insulate the second gate electrode layer 25B from the source electrode 22A and the drain electrode 22B to prevent short circuits and protect the second gate electrode layer 25B.

The source electrode 22A and the drain electrode 22B are inserted through the interlayer dielectric layer 26, the second gate insulating layer 24B, and the first gate insulating layer 24A in the gate structure layer to connect two ends of the active layer 23. The first gate electrode layer 25A and the second gate electrode layer 25B are made of a metal having excellent conductivity. The first gate insulating layer 24A, the second gate insulating layer 24B, and the interlayer dielectric layer 26 are made of an inorganic material such as silicon oxide, silicon nitride, and silicon oxynitride.

As shown in FIG. 2, the TFT structure layer 2 further comprises a buffer layer 20 disposed between the underlay 1 and the active layer 23 for protecting the TFT structure layer 2. The array substrate 1000 further comprises an encapsulation layer 4. The encapsulation layer 4 covers surfaces of the light-emitting layer 3 and the TFT structure layer 2 for encapsulating and protecting the light-emitting layer 3 to prevent external pollutants from corroding the light-emitting layer 3.

The present invention further provides a display device. The display device includes the above-mentioned array substrate 1000. The display device is an OLED (organic light-emitting diode) display device. The display device may be any product having a display function, such as a mobile phone, a tablet computer, and a notebook computer.

In the array substrate 1000 of the present invention, the leads 21 in the TFT structure layer 2 have no overlapping with the light-emitting units of the light-emitting layer 3, so that the surface of each light-emitting unit is flat and even. Thereby, the luminous efficiency of the light-emitting layer 3 is improved, the display quality of the display device is enhanced, and user experience is improved.

Although the present invention has been described with reference to specific embodiments, it should be understood that these embodiments are merely illustrative of the principles and applications of the present invention, modifications may be made to these example embodiments, and other configurations may be made without departing from the spirit and protection scope of the present invention as defined by the appended claims. Dependent claims may be combined with features of the present invention in a manner different from that described in the original claims of the present invention. It will also be appreciated that features described in connection with an individual embodiment can be used in other embodiments.

What is claimed is:

1. An array substrate, comprising:
an underlay;
a thin film transistor (TFT) structure layer disposed on the underlay, the TFT structure layer comprising a plurality of leads; and
a light-emitting layer disposed on the TFT structure layer, wherein the light-emitting layer comprises a plurality of light-emitting units, each of the light-emitting units includes a light-emitting region, and a projection of the leads projected on the underlay has no overlapping with a projection of the light-emitting regions projected on the underlay.

2. The array substrate according to claim 1, wherein the light-emitting units are arranged in an array, and a gap is provided between the light-emitting regions of each two adjacent light-emitting units, and the projection of the leads projected on the underlay falls within a projection of the gaps projected on the underlay.

3. The array substrate according to claim 1, wherein the light-emitting units comprise at least one of red light-emitting units, green light-emitting units, and blue light-emitting units.

4. The array substrate according to claim 1, wherein the TFT structure layer comprises:
a first planarization layer, wherein the leads are disposed on the first planarization layer; and
a second planarization layer disposed on the first planarization layer and covering the leads.

5. The array substrate according to claim 4, wherein the light-emitting layer comprises a first electrode disposed on the second planarization layer, two ends of the first electrode are extended out of the light-emitting region, and one end of the first electrode is connected to the lead through the second planarization layer.

6. The array substrate according to claim 5, further comprising a pixel defining layer disposed on the second planarization layer, wherein the pixel defining layer is provided with an opening arranged corresponding to the light-emitting region, and the first electrode in the light-emitting region is exposed from the opening.

7. The array substrate according to claim 4, wherein the TFT structure layer comprises a source electrode and a drain electrode, and the lead is connected to the drain electrode.

8. The array substrate according to claim 7, wherein the TFT structure layer comprises:
an active layer disposed on the underlay;
a first gate insulating layer disposed on the active layer;
a first gate electrode layer disposed on the first gate insulating layer;
a second gate insulating layer disposed on the first gate insulating layer and covering the first gate electrode layer;
a second gate electrode layer disposed on the second gate insulating layer; and
an interlayer dielectric layer disposed on the second gate insulating layer and covering the second gate electrode layer;
wherein the source electrode and the drain electrode are disposed on the interlayer dielectric layer and connected to the active layer through the interlayer dielectric layer, the second gate insulating layer, and the first gate insulating layer.

9. The array substrate according to claim 8, further comprising:
an encapsulation layer covering the light-emitting layer and the TFT structure layer; and
a buffer layer disposed on the underlay, wherein the active layer is disposed on the buffer layer.

10. A display device, comprising the array substrate of claim 1.
